(19) United States
(12) Patent Application Publication
(10) Pub. No.: US 2010/0151639 A1
(43) Pub. Date: Jun. 17, 2010

(54) METHOD FOR MAKING A THERMALLY-STABLE SILICIDE

(75) Inventors: Shau-Lin Shue, Hsinchu (TW); Chen-Hua Yu, Hsinchu (TW); Cheng-Tung Lin, Jhudong Township (TW); Chii-Ming Wu, Taipei (TW); Shih-Wei Chou, Taipei (TW); Gin Jei Wang, Taipei City (TW); CP Lo, Hsin-Chu (TW); Chih-Wei Chang, Hsinchu (TW)

Correspondence Address: HAYNES AND BOONE, LLP;IP Section, 2323 Victory Avenue, Suite 700, Dallas, TX, 75219, US

(73) Assignee: TAIWAN SEMICONDUCTOR MANUFACTURING COMPANY, LTD., Hsin-Chu (TW)

(21) Appl. No.: 12/712,518

(22) Filed: Feb. 25, 2010

Related U.S. Application Data
(63) Continuation of application No. 11/389,309, filed on Mar. 27, 2006, now abandoned.

(51) Int. Cl. H01L 21/336; H01L 21/28

(52) U.S. Cl. 438/197; 438/592; 257/E21.409; 257/E21.19

(57) ABSTRACT

Provided is a method of fabrication a semiconductor device that includes providing a semiconductor substrate, forming a gate structure over the substrate, the gate structure including a gate dielectric and a gate electrode disposed over the gate dielectric, forming source/drain regions in the semiconductor substrate at either side of the gate structure, forming a metal layer over the semiconductor substrate and the gate structure, the metal layer including a refractory metal layer or a refractory metal compound layer; forming an alloy layer over the metal layer; and performing an annealing thereby forming metal alloy silicides over the gate structure and the source/drain regions, respectively.

### PRIORITY DATA

This application is a continuation application of application Ser. No. 11/389,309, filed Mar. 27, 2006, entitled “Method for Making a Thermally Stable Silicide,” the entire disclosure of which is incorporated herein by reference.

### TECHNICAL FIELD

The present disclosure generally relates to a semiconductor device and a method of making a semiconductor device. More particularly, this present disclosure relates to the formation of silicides on semiconductor devices. The present disclosure provides a simple method to improve alloy silicide thermal stability, having a large post silicidation temperature range.

### DESCRIPTION OF THE RELATED ART

Silicides, which are compounds formed from a metal and silicon, are commonly used for contacts in semiconductor devices. Silicide contacts provide a number of advantages over contacts formed from other materials, such as aluminum or polysilicon. Silicide contacts are thermally stable, have lower resistivity than polysilicon, and are good ohmic contacts. Silicide contacts are also reliable, since the silicidation reaction eliminates many defects at an interface between a contact and a device feature.

A common technique used in the semiconductor manufacturing industry is self-aligned silicide (“salicide”) processing. Salicide processing is used in the fabrication of high-speed complementary metal oxide semiconductor (CMOS) devices. The salicide process converts the surface portions of the source, drain, and gate silicon regions into a silicide. Salicide processing involves the deposition of a metal that undergoes a silicidation reaction with silicon (Si), but not with silicon dioxide or silicon nitride. In order to form salicide contacts on source, drain, and gate regions of a semiconductor wafer, oxide spacers are provided next to the gate regions. The metal is then blanket deposited on the wafer. After heating the wafer to a temperature at which the metal reacts with the silicon of the source, drain, and gate regions to form contacts, unreacted metal is removed. Silicide contact regions remain over the source, drain, and gate regions, while unreacted metal is removed from other areas.

FIGS. 1(a)-1(d) illustrate a conventional salicide process. In FIG. 1(a), a substrate 100 is a conventional semiconductor substrate, such as a single-crystal silicon substrate, which may be doped p-type or n-type. Active regions 120 are, for example, transistor source regions or drain regions. Active regions 120 are conventionally isolated from active regions of other devices by field oxide regions 110. Field oxide regions 110 may be formed by local oxidation of silicon (LOCOS) methods, or by shallow trench isolation (STI) methods, for example. Active regions 120 may be n-type or p-type doped silicon, and may be formed according to known methods.

A conventional gate region 130 is formed on a gate oxide 125. Gate region 130 may comprise doped polysilicon. Spacers 140, which may be oxide spacers, are formed on the sidewalls of gate region 130.

In FIG. 1(b), a metal alloy layer 150 is deposited over the surface of substrate 100. Metal alloy layer 150 comprises NiX, where X is an alloying additive. While Ni is used in this example of metal alloy layer 150, other metals may be used.

After deposition of metal alloy layer 150, two rapid thermal anneal (RTA) steps are performed to achieve silicidation. During the silicidation process, silicon from active regions 120 and gate region 130 diffuses into metal alloy layer 150, and/or metal from metal alloy layer 150 diffuses into silicon-containing active regions 120 and gate region 130. One or more metal silicide regions form from this reaction. When the metal alloy layer 150 includes a metal that, upon heating, forms a silicide with elemental silicon (crystalline, amorphous, or polycrystalline), but not with other silicon-containing molecules (like silicon oxide or silicon nitride), the silicide is termed a salicide.

FIG. 1(c) illustrates the result of the two RTA steps. The first RTA step forms a Ni-rich alloy silicide layer, such as Ni₂XSi (not shown). The second RTA step forms a lower Ni content Ni alloy silicide (NiXSi). FIG. 1(c) thus shows a Ni alloy silicide 160 over gate region 130 and in active regions 120. Unreacted or not fully reacted metal alloy layer 150 remains over spacers 140.

As shown in FIG. 1(d), after silicidation, the unreacted metal alloy layer 150 is removed, for example, by a selective etch process. If the metal alloy layer 150 includes Ni, unreacted Ni/Ni alloy may be removed by wet chemical stripping. After removal of the unreacted metal, the remaining silicide regions provide electrical contacts for coupling the active regions and the gate region to other features on the semiconductor device.

In the conventional process shown in FIGS. 1(a)-1(d), commonly used salicide materials include TiSi_{y}, NiₓSi_{y}, PtSi, Pd₂Si, and NiSi, among others. Although NiSi provides some advantages over TiSi₂ and CoSi₂, for example, such as lower silicon consumption during silicidation, it is not widely used because of the difficulty in forming NiSi rather than the higher resistivity nickel di-silicide, NiSi₂. Even though back end processing temperatures below 500° C. can now be achieved, forming NiSi without significant amounts of NiSi₂ remains a challenge, since formation of NiSi₂ has been seen at temperatures as low as about 450° C. Furthermore, the thermal stability of silicides formed from pure Ni, Ti, Co, Pt, or Pd was not sufficient because of easy agglomeration occurring during high temperature processing. In addition, the conventional method described above has problems caused by native oxide left behind after processing.

The present invention is directed to overcome one or more of the problems of the related art.

### SUMMARY

One of the broader forms of an embodiment of the present invention involves a method of fabricating a semiconductor device. The method includes providing a semiconductor substrate; forming a gate structure over the substrate, the gate structure including a gate dielectric and a gate electrode disposed over the gate dielectric; forming source/drain regions in the semiconductor substrate at either side of the gate structure; forming a metal layer over the semiconductor substrate and the gate structure, the metal layer including one of a refractory metal layer and a refractory metal compound layer; forming an alloy layer over the metal layer; and performing an annealing thereby forming metal alloy silicides over the gate structure and the source/drain regions, respectively.

Another one of the broader forms of an embodiment of the present invention involves a method of fabricating a semiconductor device. The method includes providing a silicon substrate; forming a gate structure over the substrate, the gate structure including a dielectric layer and a polysilicon layer disposed over the dielectric layer; forming source/drain regions in the substrate at either side of the gate structure; forming a metal layer over the substrate and the gate structure, the metal layer including a material selected from the group consisting of: Ti, Ta, W, Mo, and compound thereof; forming an MX alloy layer over the metal layer, wherein M includes a material selected from the group consisting of: Ti, Pt, Pd, Co, and Ni, wherein X includes an alloying additive; and performing an annealing to react the alloy layer with the respective underlying silicon of the gate structure and the substrate thereby forming a metal alloy silicide over the gate structure and the source/drain regions, respectively.

Yet another one of the broader forms of the present invention involves a method of fabricating a semiconductor device. The method includes providing a semiconductor substrate; forming a gate structure over the substrate, the gate structure including a dielectric layer and a polysilicon layer disposed over the dielectric layer; forming a metal layer over the gate structure, the metal layer including a material selected from the group consisting of: Ti, Ta, W, Mo, and compound thereof; forming an alloy layer over the metal layer, the alloy layer including a material selected from the group consisting of: Ti alloy, Pt alloy, Pd alloy, Co alloy, and Ni alloy; forming a capping layer over the alloy layer; and performing an annealing thereby forming a metal alloy silicide over the gate structure.

It is to be understood that both the foregoing general description and the following detailed description are exemplary and explanatory, and are intended to provide further explanation of the invention as claimed.

### BRIEF DESCRIPTION OF THE DRAWINGS

The accompanying drawings, which are incorporated in and constitute a part of this specification, illustrate embodiments of the invention and, together with the description, serve to explain the features, advantages, and principles of the invention.

In the drawings:

FIGS. 1(a)-1(d) illustrate cross-sectional views of part of a conventional salicide processing sequence;

FIGS. 2(a)-2(e) illustrate cross-sectional views of part of a salicide processing sequence consistent with embodiments of the present invention; and

FIG. 2(f) illustrates a perspective view of a FinFET transistor structure in which source and drain regions may be alternatively formed in a fin-type structure above the substrate.

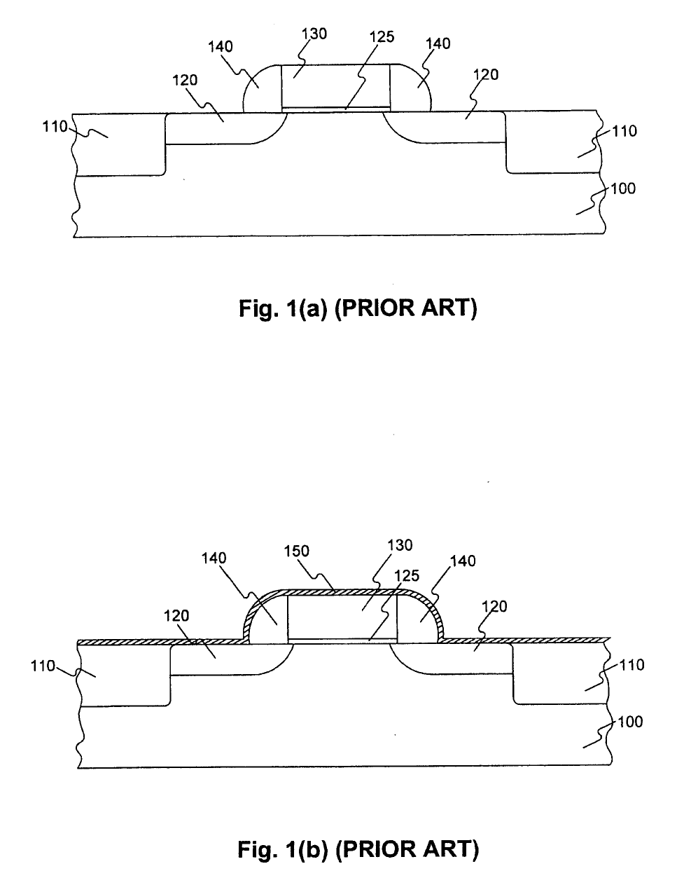

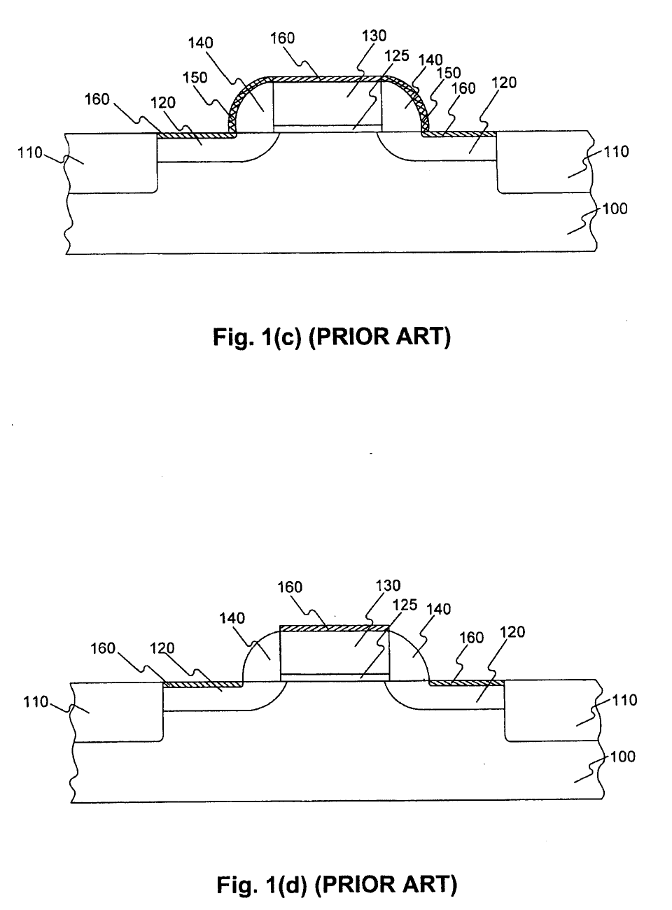

### DESCRIPTION OF THE EMBODIMENTS

Reference will now be made in detail to embodiments of the present invention, examples of which are illustrated in the accompanying drawings. Wherever possible, the same or similar reference numbers will be used throughout the drawings to refer to the same or like parts.

Embodiments consistent with the present invention provide for a simplified salicide process with better stability for NiPtSi, NiSi, PtSi, Pd₂Si, TiSi₂, CoSi₂ silicides, which allows for a larger post silicidation processing temperature range. The present invention is applicable to salicide processing in semiconductor devices having shallow junctions and/or thin silicon-on-insulator (SOI) films.

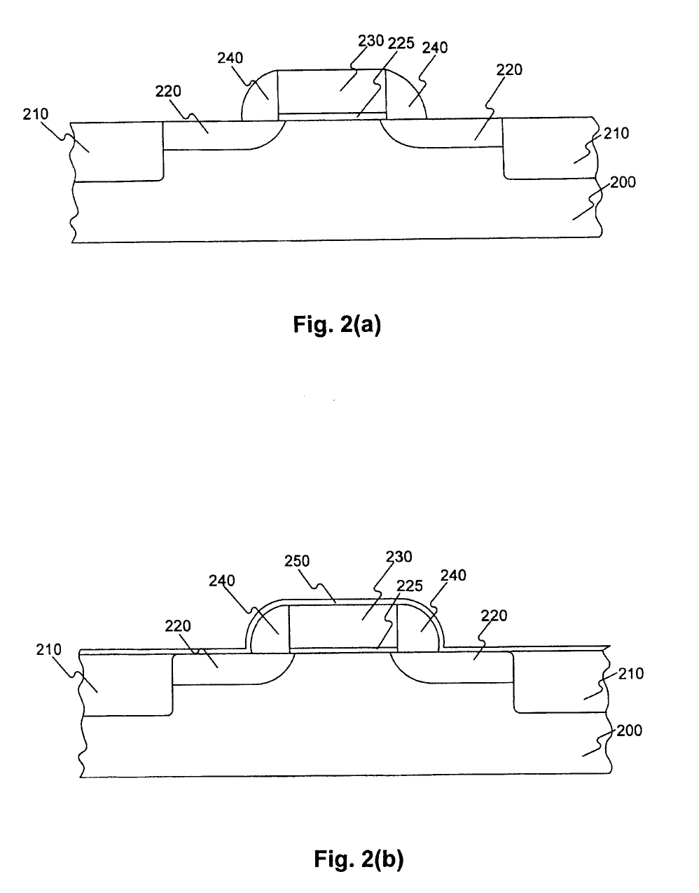

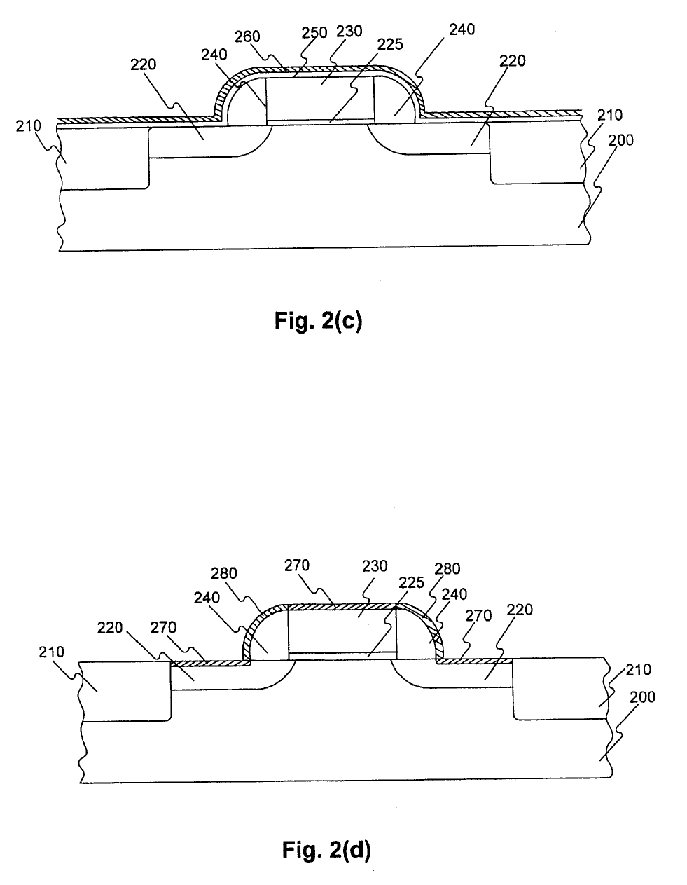

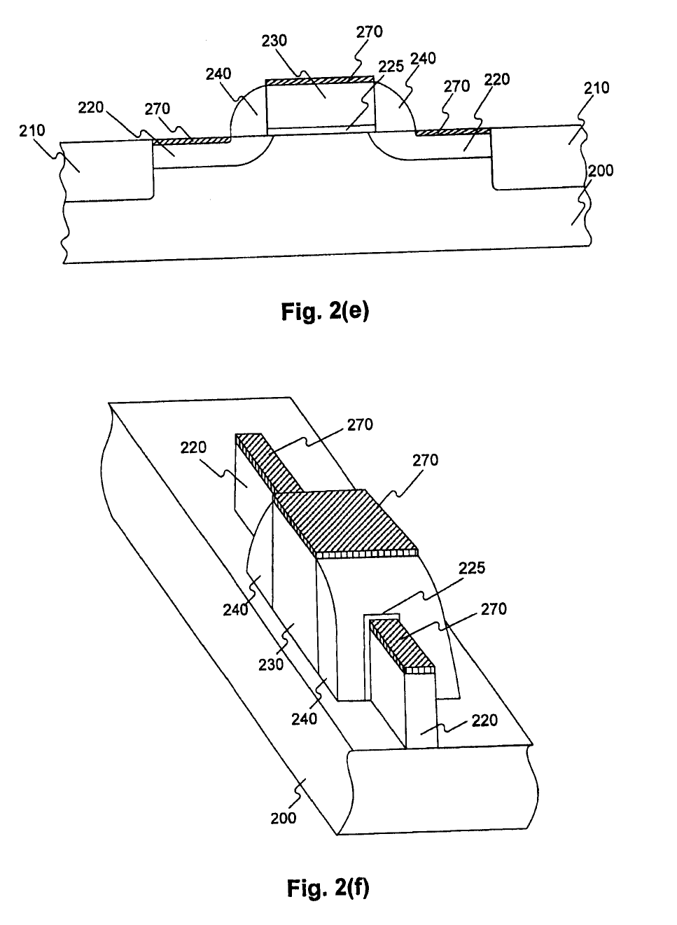

To solve problems associated with the approaches in the related art discussed above and consistent with an aspect of the present invention, package structures consistent with the present invention will next be described with reference to FIGS. 2(a)-2(e).

FIGS. 2(a)-2(e) illustrate a salicide process according to an embodiment of the present invention. In FIG. 2(a), a substrate 200 is a semiconductor substrate, such as a single-crystal silicon substrate, which may be doped p-type or n-type. Active regions are, for example, transistor source region and drain regions 20 and a gate region 230. Active regions including source and drain regions 220 and gate region 230, are isolated from active regions of other devices by isolation regions 210. Isolation regions 210 may be formed by local oxidation of silicon (LOCOS) methods, or by shallow trench isolation (STI) methods, for example. Source and drain regions 220 may be n-type or p-type doped silicon, and may be formed according to known methods.

Gate region 230 is formed on a gate dielectric 225. Gate region 230, e.g. a gate electrode, may comprise doped polysilicon. Gate dielectric 225 and gate region 230 may be formed according to known processing steps. After processing and silicide formation (described later), gate region 230 may be about 20 Å thick to about 100 Å thick, and may also be comprised of Ni, Pt, Ti, Co, Si, or a Ni alloy silicide, or any combination thereof. Preferably, gate region 230 may comprise NiPtSi. Spacers 240, which may be oxide spacers, or a combination of oxide and nitride spacers, are formed on the sidewalls of gate region 230. Consistent with an embodiment of the present invention, substrate 200 may comprise Si and at least one of SiO₂, SiON, SiN, SiCO, SiCN, SiCON, and SiGe. Further, spacers 240 may be doped with at least one of H, B, P, As, and In during the implantation step of doping substrate 200. After the profile of spacers 240 is defined, the substrate 200 may be placed in an HF dip to remove any remaining undesired oxide. Consistent with the present invention, the resultant transistor structure may be a FinFET, as shown, for example, in FIG. 2(f), in which source and drain regions 220 may be alternatively formed in a fin-type structure above substrate 200 and over which gate dielectric 225, gate region 230, and spacers 240 may be formed.

In FIG. 2(b), a layer 250 of refractory metal or refractory metal compound is formed over the surface of active regions 220 and gate region 230. Metal layer 250 may be Ti, Ta, W, or Mo, or a compound thereof that may be formed, for example, by sputter deposition using a Mo target doped with Ti. Preferably, metal layer 250 may be Ti and be about 10 Å to about 100 Å thick. More preferably, metal layer 250 may be about 10 Å to about 20 Å thick. Metal layer 250 may be formed, for example, by atomic layer deposition (ALD), or any other suitable deposition process. After deposition of metal layer 250, an alloy layer 260 is deposited as shown in FIG. 2(c). Alloy layer 260 may be deposited by any suitable process. Alloy layer 260 may be defined as an MX alloy, where M is selected from the group consisting of Ti, Pt, Pd, Co, and Ni, and X includes an alloying additive. The alloying additive may be selected from the group consisting of: C, Al, Si, Sc, Ti, V, Cr, M, Fe, Co, Ni, Cu, Ge, Y, Zr, Nb, Mo, Ru, Rh, Pd, In, Sn, La, Hf, Ta, W, Re, Ir, Pt, Ce, Pr, Nd, Sm, Eu, Gd, Tb, Dy, Ho, Er, Tm, Yb, Lu, and mixtures thereof. Further, an optional TiN cap layer (not shown) may be deposited on alloy layer 260.

The device shown in FIG. 2(c) is then subjected to an annealing step, for example, a rapid thermal anneal (RTA) step, to achieve silicidation by reaction of alloy layer 260 with underlying Si. Preferably, only one annealing step is performed, though, two annealing steps could be performed without departing from the scope of the invention. The annealing step that forms the salicide may be performed for about 10 seconds to about 180 seconds, at a temperature of about 300° C. to about 500° C., and in an atmosphere of N₂, He, or in a vacuum. Consistent with the present invention, the annealing step may be performed in a furnace, by rapid thermal anneal (RTA), in a physical vapor deposition (PVD) chamber, or on a hot plate. Preferably, the anneal step is a RTA. When the alloy layer 260 includes metal that, upon heating, forms a silicide with elemental silicon (crystalline, amorphous, or polycrystalline), but not with other silicon-containing molecules (like silicon oxide or silicon nitride), the silicide is termed a salicide.

A result of the salicide process is shown in FIG. 2(d), which illustrates a Ni alloy silicide 270 on gate region 230 and in active regions 220, and an unreacted or not fully reacted metal layer 280 on spacers 240. Preferably, Ni alloy silicide 270 may be NiPtSi. Alternatively, the present invention contemplates a variety of possible silicide phases, including, but not limited to, Ni₂₍ₓ₎Pt₍₁₋₂₍ₓ₎₎Si.

As shown in FIG. 2(e), after the salicide process, the unreacted metal alloy layer 280 is removed, for example, by a selective etch process. Unreacted metal alloy layer 280 may be removed by wet chemical stripping or a dry etching method. After removal of the unreacted metal, the remaining Ni alloy silicide 270, shown on gate region 230 and in active regions 220, provides electrical contacts for coupling the active regions and the gate region to other features on the semiconductor device. Consistent with the present invention, a contact etch stop (CESL) may be formed on top of Ni alloy silicide 270.

It will be apparent to those skilled in the art that various modifications and variations can be made in the disclosed structures and methods without departing from the scope or spirit of the invention. Other embodiments of the invention will be apparent to those skilled in the art from consideration of the specification and practice of the invention disclosed herein. It is intended that the specification and examples be considered exemplary only, with a true scope and spirit of the invention being indicated by the following claims.

What is claimed:

1. A method of fabricating a semiconductor device, comprising:
providing a semiconductor substrate;
forming a gate structure over the substrate, the gate structure including a gate dielectric and a gate electrode disposed over the gate dielectric;
forming source/drain regions in the semiconductor substrate at either side of the gate structure;
forming a metal layer over the semiconductor substrate and the gate structure, the metal layer including one of a refractory metal layer and a refractory metal compound layer;
forming an alloy layer over the metal layer; and
performing an annealing thereby forming metal alloy silicides over the gate structure and the source/drain regions, respectively.

2. The method of claim 1, wherein forming the metal layer includes forming the metal layer of a material selected from the group consisting of: Ti, Ta, W, Mo, and compound thereof.

3. The method of claim 1, wherein forming the alloy layer includes forming an MX alloy layer, wherein M includes a material selected from the group consisting of: Ti, Pt, Pd, Co, and Ni, wherein X includes an alloying additive.

4. The method of claim 3, wherein the alloying additive is a material selected from the group consisting of: C, Al, Si, Sc, Ti, V, Cr, M, Fe, Co, Ni, Cu, Ge, Y, Zr, Nb, Mo, Ru, Rh, Pd, In, Sn, La, Hf, Ta, W, Re, Ir, Pt, Ce, Pr, Nd, Sm, Eu, Gd, Tb, Dy Ho, Er, Tm, Yb, Lu, and combination thereof.

5. The method of claim 1, wherein forming the metal layer includes forming a layer of Ti.

6. The method of claim 2, wherein forming the alloy layer include forming a layer of Ni alloy.

7. The method of claim 1, further comprising forming a capping layer of TiN over the alloy layer prior to performing the annealing.

8. A method of fabricating a semiconductor device, comprising:
providing a silicon substrate;
forming a gate structure over the substrate, the gate structure including a dielectric layer and a polysilicon layer disposed over the dielectric layer;
forming source/drain regions in the substrate at either side of the gate structure;
forming a metal layer over the substrate and the gate structure, the metal layer including a material selected from the group consisting of: Ti, Ta, W, Mo, and compound thereof;
forming an MX alloy layer over the metal layer, wherein M includes a material selected from the group consisting of: Ti, Pt, Pd, Co, and Ni, wherein X includes an alloying additive; and
performing an annealing to react the alloy layer with the respective underlying silicon of the gate structure and the substrate thereby forming a metal alloy silicide over the gate structure and the source/drain regions, respectively.

9. The method of claim 8, further comprising forming a capping layer over the alloy layer prior to performing the annealing.

10. The method of claim 9, wherein forming the capping layer includes forming a TiN layer.

11. The method of claim 8, wherein forming the metal layer includes forming a Ti layer.

12. The method of claim 11, wherein forming the alloy layer includes forming a Ni alloy layer.

13. The method of claim 8, wherein forming the metal layer includes forming the metal layer having a thickness ranging from about 4 Å to about 20 Å; and
wherein forming the alloy layer includes forming the alloy layer having a thickness ranging from about 50 Å to about 200 Å.

14. The method of claim 8, wherein the metal alloy silicide includes a material selected from the group consisting of: NiPtSi, NiPdSi, CoPtSi₂, and CoPdSi₂.

15. A method of fabricating a semiconductor device, comprising:
providing a semiconductor substrate;
forming a gate structure over the substrate, the gate structure including a dielectric layer and a polysilicon layer disposed over the dielectric layer;
forming a metal layer over the gate structure, the metal layer including a material selected from the group consisting of: Ti, Ta, W, Mo, and compound thereof;
forming an alloy layer over the metal layer, the alloy layer including a material selected from the group consisting of: Ti alloy, Pt alloy, Pd alloy, Co alloy, and Ni alloy;
forming a capping layer over the alloy layer; and
performing an annealing thereby forming a metal alloy silicide over the gate structure.

16. The method of claim 15, wherein forming the capping layer includes forming a TiN layer.

17. The method of claim 15, wherein forming the metal layer includes forming a TiN layer.

18. The method of claim 15, wherein forming the alloy layer includes forming a Ni alloy layer.

19. The method of claim 15, wherein the metal alloy silicide includes a material selected from the group consisting of: NiPtSi, NiPdSi, CoPtSi₂, and CoPdSi₂.

20. The method of claim 15, wherein performing the annealing includes performing the annealing for about 10 seconds to about 180 seconds, at a temperature ranging from about 300° C. to about 500° C., and in an atmosphere of N₂, He, or vacuum.
